(19) United States
(12) Patent Application Publication
(10) Pub. No.: US 2026/0318973 A1
(43) Pub. Date: Oct. 15, 2026

(54) BUSBAR INSPECTION SYSTEM

(71) Applicant: Lear Corporation, Southfield, MI (US)

(72) Inventors: Jason Hinds, Waterford, MI (US); Arthur Hurlburt, Canton, MI (US); Tomas Godoy, Millenium, N.L. (MX)

(21) Appl. No.: 19/175,595

(22) Filed: Apr. 10, 2025

(51) Int. Cl. G01R 31/08; H02G 5/04

(52) U.S. Cl. CPC G01R 31/083; H02G 5/04

(57) ABSTRACT

A system includes a housing, one or more busbars, and one or more conductive cables disposed between the housing and the one or more busbars. The one or more busbars may comprise one or more apertures disposed in substantial alignment with one or more channels of the housing. Additionally, the one or more conductive cables may be visible through the one or more apertures for visual inspection at the one or more channels. The one or more channels may correspond to areas where at least one of the one or more conductive cables are capable of pinching while connecting at least one busbar of the one or more busbars to the housing. Further, connecting the one or more busbars to the housing limits movement of the one or more conductive cables.

### TECHNICAL FIELD

The present disclosure generally relates to assemblies that may include a housing, one or more conductive cables, and one or more busbars that may, for example, include one or more apertures for visual inspection of the one or more conductive cables.

### BRIEF DESCRIPTION OF THE DRAWINGS

While the claims are not limited to a specific illustration, an appreciation of various aspects may be gained through a discussion of various examples. The drawings are not necessarily to scale, and certain features may be exaggerated or hidden to better illustrate and explain an innovative aspect of an example. Further, the exemplary illustrations described herein are not exhaustive or otherwise limiting, and embodiments are not restricted to the precise form and configuration shown in the drawings or disclosed in the following detailed description. Exemplary illustrations are described in detail by referring to the drawings as follows:

FIG. 1A is a top view generally illustrating an embodiment of a busbar inspection system according to teachings of the present disclosure.

FIG. 1B is a top-sectional view generally illustrating an embodiment of a busbar inspection system according to teachings of the present disclosure.

FIG. 2 is a top view generally illustrating an embodiment of first busbar of the busbar inspection system according to teachings of the present disclosure.

FIG. 3 is a top view generally illustrating an embodiment of second busbar of the busbar inspection system according to teachings of the present disclosure.

FIG. 4 is a top view generally illustrating an embodiment of third busbar of the busbar inspection system according to teachings of the present disclosure.

FIG. 5 is a top view generally illustrating an embodiment of a busbar inspection system according to teachings of the present disclosure.

FIG. 6A is a perspective view generally illustrating an embodiment of a pinched conductive cable of the busbar inspection system according to teachings of the present disclosure.

FIG. 6B is a perspective view generally illustrating an embodiment of a pinched conductive cable of the busbar inspection system according to teachings of the present disclosure.

FIG. 7 is a side view generally illustrating an embodiment of a camera system visually confirming the assembly of the one or more conductive cables between the housing and the one or more busbars.

### DETAILED DESCRIPTION

Reference will now be made in detail to embodiments of the present disclosure, examples of which are described herein and illustrated in the accompanying drawings. While the present disclosure will be described in conjunction with embodiments and/or examples, they do not limit the present disclosure to these embodiments and/or examples. On the contrary, the present disclosure covers alternatives, modifications, and equivalents.

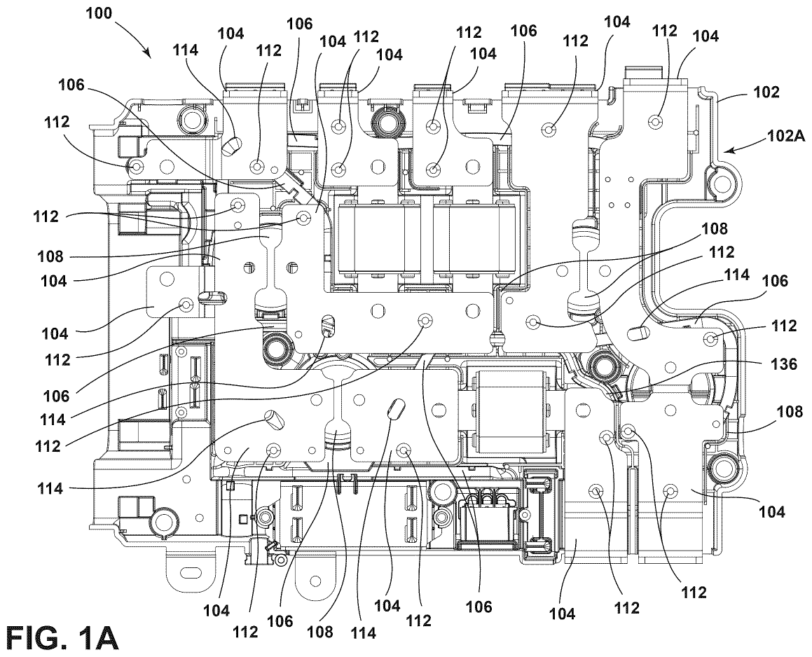

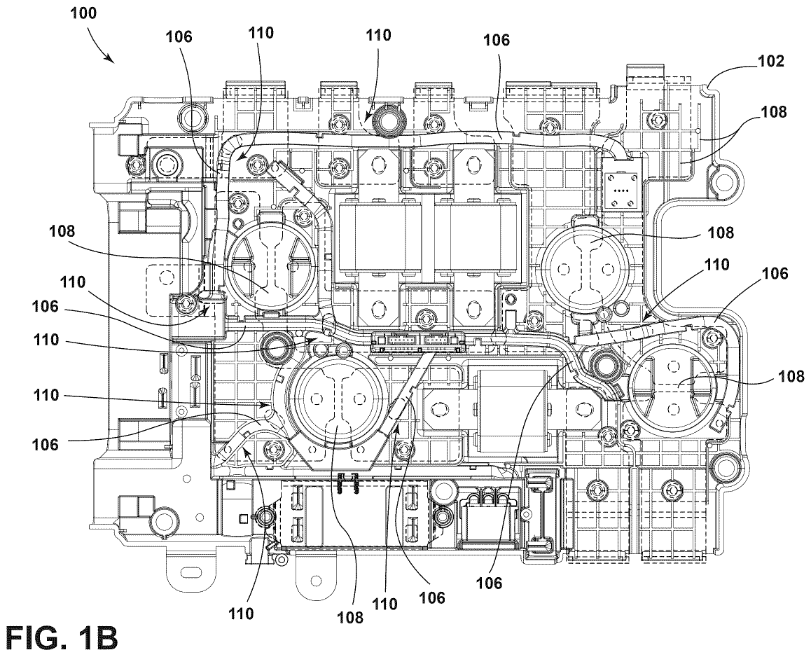

In embodiments, such as generally illustrated in FIG. 1A, a busbar inspection system 100 may include a housing 102, one or more busbars 104, and/or one or more conductive cables 106. The housing 102 may be configured to accommodate a wide variety of electrical components, while providing efficient and/or organized electrical interconnectivity. In examples, the housing 102 may be configured to serve as a structural enclosure, providing mechanical stability and/or thermal management for the contained electrical components, while providing an integrated power distribution system. With embodiments, the housing 102 may include one or more of a variety of shapes, sizes, and/or configurations. For example and without limitation, as shown in FIGS. 1A and 1B, the housing 102 may be generally rectangular shaped. The housing 102 may be any suitable shape to accommodate a variety of components and/or currents/loads.

In examples, the housing 102 may provide an efficient and reliable framework for various electrical systems, ensuring the secure enclosure of components such as power supplies, controllers, sensors, and other electronic components. The housing 102 may serve as a protective structure that shields the internal components from environmental factors such as dust, moisture, and mechanical stress; and additionally, as an integrated system that enhances the distribution and/or management of electrical power throughout the electrical components within the housing 102.

With embodiments, the housing 102 may be made from durable, insulating materials to provide mechanical support and/or electrical isolation. The housing 102 may include one or more supports 108 (e.g., mounting points) that securely hold/guide electrical components in position, and further, the one or more supports 108 may form one or more channels 110 for the one or more conductive cables 106 to be routed. The housing 102 may include one or more of a variety of materials, such as a variety of polymer composite. Additionally, the overall configuration of the housing 102 may be modular in nature, providing a flexible integration of different types of electrical systems depending on the specific application. The busbar inspection system 100 may be used in a wide range of applications, including automotive, industrial, and consumer electronics.

In embodiments, the one or more busbars 104 of the housing 102 may be disposed on a top surface 102A of the housing 102, which may serve as one or more central power distribution nodes. The one or more busbars 104 may provide a direct, low-resistance pathway for electrical current, reducing the need for complex wiring configurations and minimizing power losses. The placement of the one or more busbars 104 on the top surface 102A of the housing 102 may be optimized for ease of connection to internal components, which may streamline the assembly process and provide for more compact and organized internal layouts. Such an arrangement may also facilitate improved thermal management, as the placement of the one or more busbars 104 on the top surface 102A of the housing 102 may contribute to more effective heat dissipation, limiting the likelihood that electrical components inside the housing 102 to overheat.

With examples, the one or more conductive cables 106 may be disposed between the one or more supports 108, as well as the one or more busbars 104, to establish electrical connections between the one or more busbars 104 and various internal electrical components (e.g., disposed within the housing 102). The one or more conductive cables 106 may serve as conductive pathways that transmit power and signals from the one or more busbars 104 to the internal electrical systems/components, which may include but are not limited to power supplies, controllers, sensors, and other modular devices. By incorporating the one or more conductive cables 106, the system 100 may ensure that electrical connectivity is both reliable and efficient, facilitating proper operation of the interconnected components.

In embodiments, the one or more conductive cables 106 may be routed through one or more channels 110 (e.g., recesses) formed within the housing, such as via the one or more supports 108 of the housing 102. The one or more channels 110 may guide the one or more conductive cables 106 in a secure and organized manner, limiting and/or reducing movement of the one or more conductive cables 106 from during operation, maintenance, or assembly. By routing the one or more conductive cables 106 in this manner, the likelihood of mechanical wear or damage to the conductive cables 106 may be reduced over time. Moreover, routing may limit and/or reduce the one or more conductive cables 106 from interfering with other internal components, such as heat-generating systems, which could otherwise lead to performance degradation and/or component failure.

With embodiments, by positioning the one or more conductive cables 106 between the housing 102 (e.g., the one or more supports) and/or the one or more busbars 104, the system 100 may mitigate the risk of the one or more conductive cables 106 being pinched or electrically compromised during assembly and/or operation. In conventional systems, conductive cables 106 are often routed without specific structural guidance which may lead to accidental pinching or crimping during assembly. When the one or more conductive cables 106 are pinched, their insulation may be damaged, leading to potential short circuits, electrical arcing, and/or a gradual breakdown of electrical integrity over time. Said pinching of the one or more conductive cables 106 may be noticed via a visual inspection of the system (e.g., manually or via a camera system 190 and/or controller 192).

In examples, by providing channels 110 via the housing 102, movement of the one or more conductive cables 106 may be limited in at least one direction, ensuring that they are not inadvertently compressed between housing components, fasteners, or other structural elements during assembly. During assembly and/or operation, the one or more conductive cables 106 may be forced into tight spaces and/or bent at damaging angles, which may compromise the insulation and/or induce stress that leads to electrical failure. This organized routing helps maintain the electrical connections in an optimal state, ensuring the consistent performance of the system 100.

Additionally, disposing the one or more conductive cables 106 within one or more channels 110 may streamline the assembly process due to the one or more conductive cables 106 routed in predefined areas (e.g., the channels 110), assembly technicians or automated systems can easily locate and secure them, reducing the risk of human error or misalignment. Such an approach may reduce the possibility of pinched and/or compromised conductive cables 106, thus enhancing the quality control of the assembled system 100.

As generally illustrated in FIG. 1A, the one or more supports 108 may be oriented and/or connected to form the one or more channels 110. The one or more channels 110 may include one or more of a variety of shapes, sizes, and/or configurations, in part due to the variety of supports defining the one or more channels 110. The one or more channels 110 may be disposed vertically (e.g., in the Z-direction) between the one or more busbars 104 and the housing 102. The one or more supports 108 may extend in the X-direction, the Y-direction, and/or the Z-direction to form the one or more channels 110. For example and without limitation, the one or more channels 110 may be linear, curved, and/or may include one or more of a variety of dimensions to accommodate a variety of conductive cable 106 sizes. For example and without limitation, the one or more channels 110 may include varying heights such that larger and/or smaller conductive cables 106 may be disposed at least partially in the one or more channels 110. The one or more supports 108 may generally form a grid-like arrangement, whereby the one or more channels 110 may be disposed in a plurality of locations between the housing 102 and the one or more busbars 104 (e.g., in the Z-direction).

Such as illustrated, the one or more conductive cables 106 may be disposed within the one or more channels 110 at a variety of positions proximate the top surface 102A of the housing 102. The one or more channels 110 may be disposed generally proximate outer portions of the housing 102 (e.g., about a perimeter) and/or generally proximate a middle portion of the housing 102. As is contemplated, the one or more conductive cables 106 may be routed in a plurality of directions about a plurality of locations within the housing 102, via the one or more channels 110 to connect a variety of electrical components.

In embodiments, such as generally illustrated in FIG. 1B, the one or more busbars 104 may be disposed on a top surface 102A of the housing which may facilitate an optimized power transfer and distribution network for the components housed within. The one or more busbars 104 may include one or more of a variety of conductive materials, such as copper and/or aluminum. Further, the substantially planar shape of the one or more busbars 104 may increase surface area to reduce electrical resistance and heat buildup, allowing the electrical assembly to manage higher currents in a safer manner. The one or more busbars 104 may be dimensioned and configured to handle varying electrical loads, depending on the application's power requirements, and/or may be equipped with insulated coatings or protective layers to prevent electrical shorts and improve safety.

With examples, the one or more busbars 104 may be positioned on the top surface 102A of the housing 102 to provide direct connection with the electrical components housed within. Such an arrangement may minimize wiring complexity and/or reduce electrical resistance losses commonly associated with longer, traditional cable runs. The one or more busbars 104 may include one or more of a variety of shapes, sizes, and/or configurations to accommodate a variety of electrical configurations. For example, as seen generally in FIGS. 1A and 1B, the one or more busbars 104 may be curved, linear, rectangular, and/or include one or more flanges.

As illustrated in FIGS. 1A, 1B, 2, 3, and 4, the one or more busbars 104 may include one or more apertures for a variety of functions (e.g., connection and/or inspection). The one or more apertures may include one or more of a variety of shapes, sizes, and/or configurations. With examples, the one or more apertures may include one or more connection apertures 112 and/or one or more inspection 114 apertures. The one or more connection apertures 112 may at least partially receive a fastener 116 (e.g., or other securing member) to connect the one or more busbars 104 to the housing 102. The one or more inspection apertures 114 may facilitate confirmation/validation of the structural integrity (e.g., the conductivity and insulation) of the one or more conductive cables 106 connected between the one or more supports 108 and the one or more busbars 104. With examples, the one or more busbars 104 may include varying shapes and/or sizes and may include varying quantities of one or more connection apertures and/or one or more inspection apertures (e.g., to preserve the conductive integrity of the one or more conductive cables).

With embodiments, as illustrated in FIGS. 1A and 1B, the one or more busbars 104 may generally cover a portion (e.g., a majority) of the surface area of the housing 102. The one or more busbars 104 may be generally rectangular shaped, L-shaped, and/or may include a variety of bent/curved shapes. As shown in FIG. 1B, the one or more busbars 104 may connect with the housing 102 and/or one or more electrical components via the one or more connection apertures 112 (e.g., first apertures). The one or more connection apertures 112 may be disposed generally towards an edge of the one or more busbars 104, for example, to secure the one or more busbars 104 with the housing 102. Further, the one or more connection apertures 112 may be configured to at least partially receive a variety of fasteners 116, and/or the fasteners 116 may limit movement of the one or more busbars 104 in at least one direction (e.g., in other cases all directions). The one or more connection apertures 112 may additionally or alternatively be disposed towards a center region of the one or more busbars 104 (e.g., where the housing 102 and/or an electrical component may receive a fastener 116). The one or more connection apertures 112 may include a beveled edge to accommodate receiving a fastener 116 securing the one or more busbars 104 with the housing 102 and/or electrical components.

As illustrated in FIG. 1B, the one or more inspection apertures 114 of the one or more busbars 104 may be disposed in alignment (e.g., in the Z-direction) with portions of the one or more conductive cables 106 and/or the one or more channels 110. The one or more inspection apertures 114 may be aligned with the one or more conductive cables 106 to facilitate visual inspection of the one or more conductive cables 106. For example and without limitation, the one or more inspection apertures 114 may be positioned directly and/or at least partially in alignment (e.g., at least partially in the Z-direction) with a portion of the one or more conductive cables 106 and/or the one or more channels 110. The one or more inspection apertures 114 may include a variety of shapes and/or sizes. For example and without limitation, the one or more inspection apertures 114 may be oval-shaped, rounded, and/or circular. With embodiments, the shape of one or more inspection apertures 114 may vary with a variety of conductive cable sizes and/or channels 110.

With examples, disposing the one or more inspection apertures 114 in alignment with both: (i) a conductive cable of the one or more conductive cables 106, and (ii) a channel of the one or more channels 110 which may permit a visual inspection of the one or more conductive cables 106 via the one or more inspection apertures 114. For example and without limitation, during assembly, the one or more conductive cables 106 may be pinched by the one or more busbars 104 in regions proximate the one or more channels 110. One or more conductive cables 106 that are not be disposed completely within the one or more channels 110 may be pinched (e.g., conductively compromised) along the one or more supports 108 (e.g., support walls of the channels) as the one or more busbars 104 are connected to the housing 102 (e.g., via fasteners).

In embodiments, the one or more inspection apertures 114 may be disposed in a variety of positions about the top surface 102A of the housing 102. The one or more inspection apertures 114 may be disposed proximate regions where the one or more conductive cables 106 may be likely to be compromised (e.g., deformation/pinching of the insulative and/or conductive portion of the conductive cable 106) during assembly with the housing 102. For example and without limitation, the one or more inspection apertures 114 may be disposed substantially proximate curved and/or bent regions of the one or more channels 110 (among other regions). It may be difficult/challenging for the one or more conductive cables 106 to be placed within the one or more channels 110 at curved and/or bent regions; therefore, the one or more inspection apertures 114 may provide a visual confirmation that the one or more conductive cables 106 are disposed substantially within the one or more channels 110. The one or more inspection apertures 114 may provide a visual validation of conductive cable placement prior to securing the one or more busbars 104 with the housing 102 (e.g., potentially causing damage to the one or more conductive cables 106).

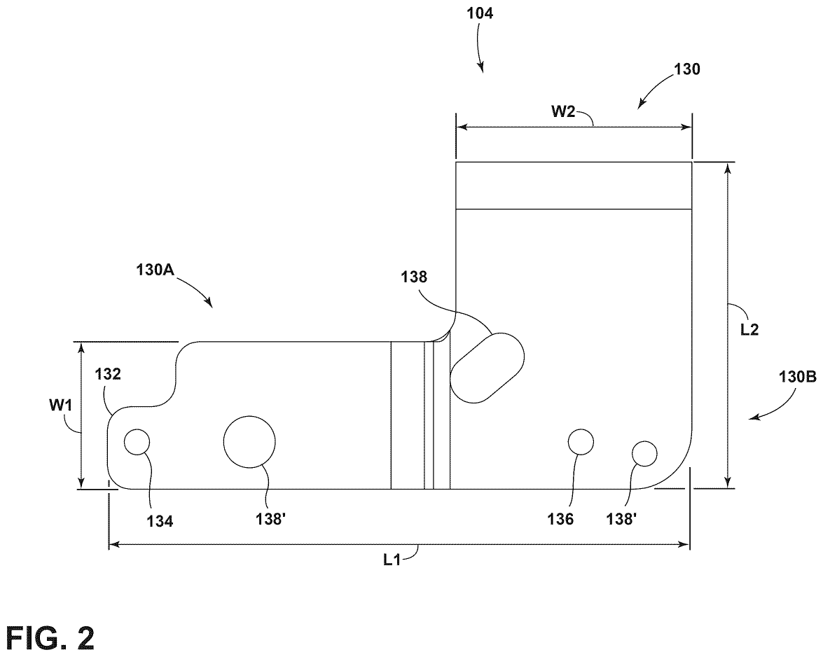

With examples, such as generally illustrated in FIGS. 2, 3, and 4, the one or more busbars 104 may include one or more of a variety of shapes, sizes, and/or configurations. Further, the one or more busbars 104 may include a variety of quantities and/or sizes of the one or more connection apertures 112 and/or the one or more inspection apertures 114 to facilitate visual inspection while maintaining conductivity of the one or more busbars 104. With examples, the location, size, and/or quantity of connection apertures 112 and/or inspection apertures 114 may correlate with the surface area of the associated busbar 104. In embodiments, the conductivity of the one or more busbars 104 may be compromised if the apertures 112, 114 are too numerous and/or large for a given busbar 104.

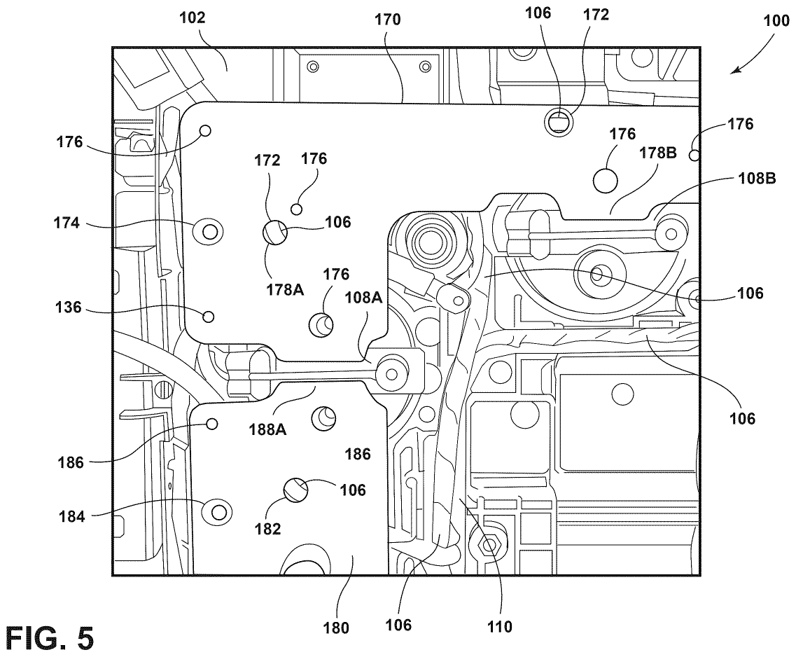

As shown in FIG. 2, a first busbar 130 of the one or more busbars 104 may include a substantially curved and/or L-shaped configuration. The first busbar 130 may include a first length L1, a second length L1, a first width W1, and/or a second width W2. Further, the first length L1 may be about twice as long as the second width W2; and/or the second length L2 may be about twice as long as the first width W1. The first length L1 may be longer than the second length L2, and/or the first width W1 may be shorter than the second width W2. Additionally, a flange 132 may extend from an edge of the first busbar 130. As shown in FIG. 5, the flange 132 may contact a portion of the housing, at least partially limiting movement in the Z-direction.

With examples, the first busbar 130 may include a first connecting aperture 134 and a second connecting aperture 136 which may limit movement of the first busbar 130 in at least one direction. The first connecting aperture 134 and/or the second connecting aperture 136 may be configured to at least partially receive a fastener to secure the first busbar 130 with the housing. The first connecting aperture 134 may be disposed substantially proximate a first end 130A of the first busbar 130. As illustrated in FIG. 2, the first connecting aperture 130 may be disposed proximate the flange 132. Further, the second connecting aperture 136 may be disposed proximate a second end 130B (e.g., opposite the first end 130A) of the first busbar 130, which may be an outer corner of the first busbar 130. The first busbar 130 may include an inspection aperture 138 that may be disposed in an inner corner of the first busbar 130. The inspection aperture 138 may include one or more of a variety of shapes and/or sizes. For example, the inspection aperture 138 may be oval-shaped. Additionally, the first busbar 130 may include one or more auxiliary apertures 138′.

Generally, the one or more inspection apertures, the one or more connection apertures, and/or the one or more auxiliary apertures may contribute to a reduction in thermal performance of the first busbar 130 (e.g., due to a lack of material at the apertures). The first busbar 130 may include about 2.2% less volume (due to the apertures) which may contribute to about a 1.3% increase in busbar temperature while conducting. Adding apertures to the first busbar 130 beyond the configuration shown in FIG. 2 may compromise the functionality of the first busbar 130 (e.g., leading to overheating).

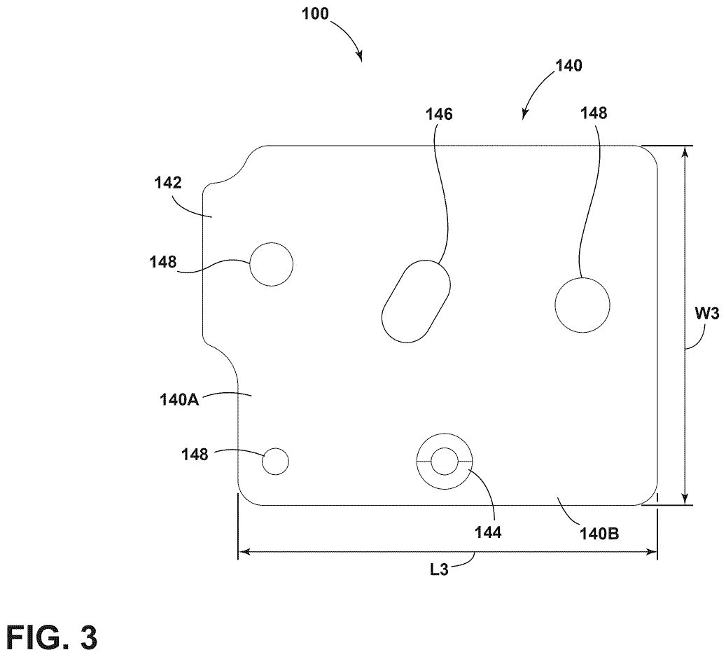

As illustrated in FIG. 3, a second busbar 140 of the one or more busbars 104 may include a generally rectangular/square shape. The second busbar 140 may include a length L3 and a width W3, which may generally be the same. A flange 142 may extend from a first edge 140A of the second busbar 140. Further, the second busbar 140 may include a connection aperture 144 and/or an inspection aperture 146. With embodiments, the connection aperture 144 may be disposed proximate a second edge 140B of the second busbar 150 (e.g., the first edge 140A may be disposed perpendicular to the second edge 140B). Additionally, the second busbar 140 may include one or more auxiliary apertures 148 that may be selected (e.g., size and/or position) to control the temperature of the second busbar 140. The one or more auxiliary apertures 148 may include a variety of shapes and sizes (e.g., circular as shown in FIG. 3). The one or more auxiliary apertures 148 may improve cooling/heat dissipation of the second busbar 140.

In examples, the one or more inspection apertures, the one or more connection apertures, and/or the one or more auxiliary apertures may contribute to a reduction in thermal performance of the second busbar 140 (e.g., due to a lack of material at the apertures). The second busbar 140 may include about 2.8% less volume (due to the apertures) which may contribute to about a 2.6% increase in busbar temperature while conducting. Adding apertures to the second busbar 140 beyond the configuration shown in FIG. 3 may compromise the functionality of the second busbar 140 (e.g., leading to overheating).

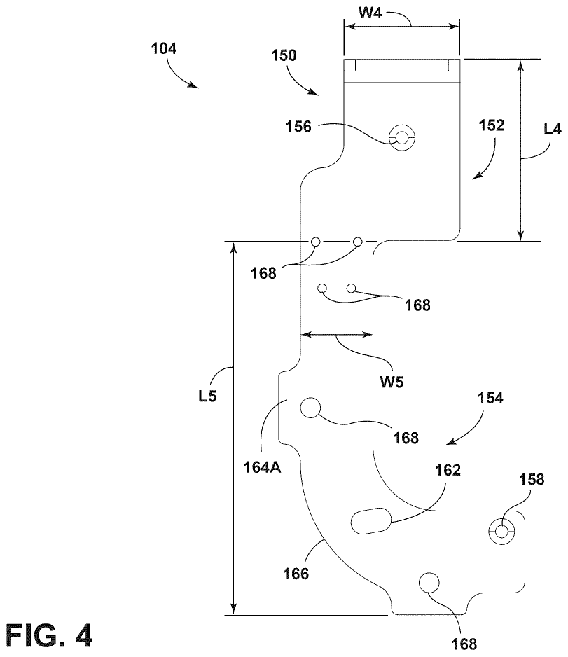

As generally shown in FIG. 4, a third busbar 150 of the one or more busbars 104 may include one or more of a variety of shapes, sizes, and/or configurations. For example and without limitation, the third busbar 150 may be generally rectangular, curved, and/or L-shaped. The third busbar 150 may include a first portion 152 connected with a second portion 154 (e.g., formed as a single conductive piece). In embodiments, the first portion 152 may be rectangular-shaped, which may connect with a curved (e.g., L-shaped) second portion 154. The first portion 152 may include a first connection aperture 156 for securing a first end 150A of the third busbar 150 with the housing 102. Further, the first connection aperture 156 may be disposed generally in an off-center region of the first portion 152. The first portion 152 may include a length L4 and a width W4, where the length L4 is generally longer than the width W4 (e.g., forming a rectangular shape).

With embodiments, the second portion 154 may include a second connection aperture 158 for securing the second end 150B of the third busbar 150 with the housing. The second connection aperture 158 may be disposed in a corner 160 of the second portion 154. Further, the second portion 154 may include a length L5 and a width W5, where the length L5 is generally longer than the width W5. Additionally, the length L5 of the second portion 154 may be longer than the length L4 of the first portion 152. The width W5 of the second portion 154 may be shorter than the width W4 of the first portion 152. Further, the length L5 of the second portion 154 may be about twice as long as the length L4 of the first portion 152.; and/or the width W5 of the second portion 154 may be about 40% of the width W4 of the first portion 152. As can be seen in FIG. 4, the second portion 154 may be a curved L-shape extending from the rectangular first portion 152.

In examples, the second portion 154 may include an inspection aperture 162 to view one or more conductive cables 106 disposed within a channel 110 underneath the one or more busbars 104. The inspection aperture 162 may be disposed in a middle region of the third busbar 150 (e.g., the second portion 154 thereof). The inspection aperture 162 may be curved, circular, and/or oval-shaped such that a sufficient portion of the one or more conductive cables is visible. Additionally, the second portion 154 of the third busbar 150 may include a first flange 164A and/or a second flange 164B extending from an outer edge 166 (e.g., which may contact a portion of the housing 102 to limit movement in the Z-direction). The third busbar 150 may include one or more auxiliary apertures 168 that may be selected to control the temperature of the third busbar 150. The one or more auxiliary apertures 168 may include a variety of shapes and sizes (e.g., circular as shown in FIG. 3). The one or more auxiliary apertures 168 may improve cooling/heat dissipation of the third busbar 150.

In examples, the one or more inspection apertures, the one or more connection apertures, and/or the one or more auxiliary apertures may contribute to a reduction in thermal performance of the third busbar 150 (e.g., due to a lack of material at the apertures). The third busbar 150 may include about 1.2% less volume (due to the apertures) which may contribute to about a 1.4% increase in busbar temperature while conducting. Adding apertures to the third busbar 150 beyond the configuration shown in FIG. 3 may compromise the functionality of the third busbar 150 (e.g., leading to overheating).

With embodiments, such as generally illustrated in FIG. 5, the system 100 may include a fourth busbar 170 and/or a fifth busbar 180. The fourth busbar 170 may include one or more inspection apertures 172, connection apertures 174, and/or auxiliary apertures 176. Similarly, the fifth busbar 180 may include one or more inspection apertures 182, connection apertures 184, and/or auxiliary apertures 186. As shown, the one or more conductive cables 106 may be routed between (e.g., in the Z-direction) the one or more busbars 104 and the housing 102 (e.g., the channels 110). The one or more conductive cables 106 may be routed beneath multiple busbars 104 and/or may extend substantially along/across the housing 102. Further, the one or more conductive cables 106 may be visible through the one or more inspection apertures 176, 186 for visual inspection/confirmation.

In examples, the fourth busbar 170 may include a first flange 178A and/or a second flange 178B extending outwardly. The housing 102 may include a first support 108A and/or a second support 108B that may contact the first flange 178A and/or the second flange 178B, respectively. The first support 108A and/or the second support 108B may be substantially planar/flat portions that may be complimentary in shape to the substantially planar one or more busbars 104. Further, the first support 108A and/or the second support 108B may limit movement of the fourth busbar 170 and/or the fifth busbar 180 in the Z-direction. Additionally, the fifth busbar 180 may include a first flange 188A that may contact the second support 108B of the housing, limiting movement of the fifth busbar 180.

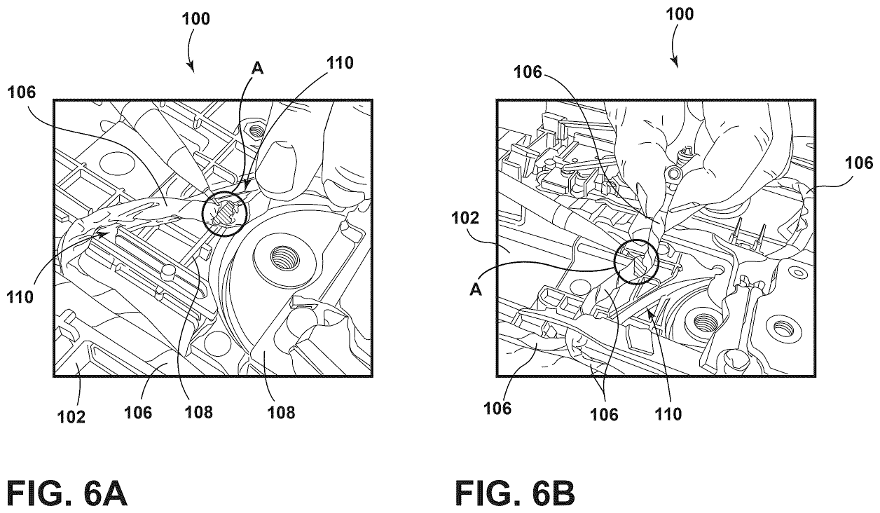

With embodiments, such as generally illustrated in FIGS. 6A and 6B, the one or more conductive cables 106 may be compromised as the one or more busbars 104 are connected to the housing 102 (e.g., via one or more fasteners). In cases where visual inspection may not be confirmed (e.g., confirmation that the one or more conductive cables 106 are disposed substantially within the one or more channels 110) the channel 110 may contact the one or more conductive cables 106 causing damage. Damage may include compromising the electrical conductivity of the one or more conductive cables 106 and/or deforming the insulative layer of the one or more conductive cables 106. As can be seen in FIGS. 6A and 6B, the one or more conductive cables 106 may be misaligned with the channel 110 (e.g., the one or more conductive cables 106 may not be substantially disposed within the channel 110). Further, the one or more conductive cables 106 may be displaced at least partially with respect to the channel 110 causing contact between the one or more supports 108, the one or more conductive cables 106, and/or the one or more busbars 104 (resulting in damaged portion A). As the one or more busbars 104 may be secured with the housing 102, one or more conductive cables 106 may be pinched between the one or more busbars 104 and the one or more supports 108 (e.g., in the Z-direction). The one or more inspection apertures 114 may be disposed in locations about the housing where damage (e.g., misalignment) may be likely to occur between the one or more conductive cables 106 and the supports 108 and/or channels 110. Such locations may also correspond to connections with emergency power and/or foundational wiring for the system and electrical components disposed within the housing 102. Such foundational wiring may provide basic functions of the electrical components disposed within the housing 102 and/or connected with the one or more busbars 104.

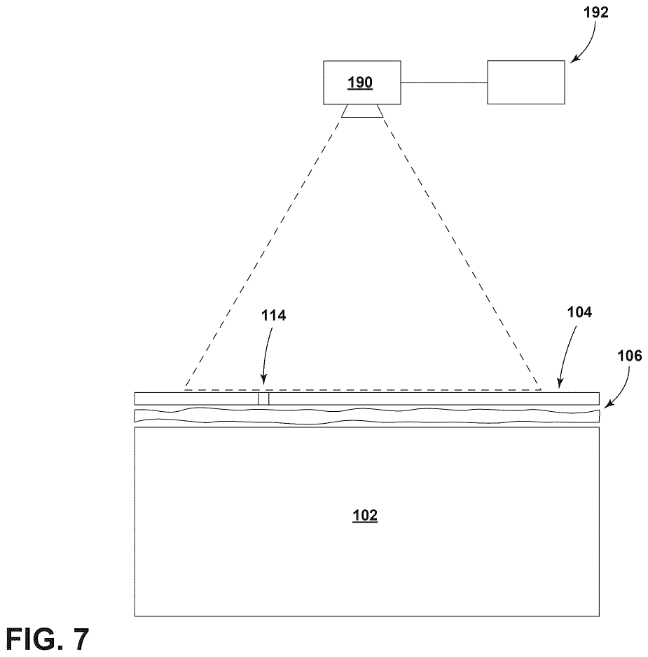

For example and without limitation, as illustrated in FIG. 7, the busbar inspection system 100 may include and/or be connected with a camera system 190 (e.g., a camera) disposed in alignment with the one or more inspection apertures 114. The camera system 190 may be communicatively connected with a controller 192 to process received information (e.g., such as a position of the one or more conductive cables 106). The camera system 190 may be positioned to view a portion of the one or more conductive cables 106 through the one or more inspection apertures 114 to confirm proper/successful assembly of the one or more busbars 104 with the housing 102. The one or more conductive cables 106 may be disposed below (e.g., aligned in the Z-direction) the one or more inspection apertures 114 and may be at least partially seen/viewed through the one or more inspection apertures 114 when the one or more conductive cables 106 are properly disposed within the one or more channels 110 (e.g., see FIGS. 1A and 1B). If one or more of the conductive cables 106 are not properly disposed within the one or more channels 110, the camera system 190, via the controller 192, may not detect (e.g., view) the one or more conductive cables 106. With embodiments, the camera system 190 may be disposed at a distance from the one or more busbars 104 (e.g., between about 20 mm and about 1 m, among other distances) to capture the one or more inspection apertures 114 within a single image/video (e.g., a field of view). Such an image/video may be processed via the controller 192 connected with the camera system 190.

With embodiments, a method of inspecting a busbar system 100 may include providing a housing 102, one or more busbars 104, and/or one or more conductive cables 106 disposed between the housing 102 and the one or more busbars 104. The method may include providing a controller 192 and/or a camera system 190, wherein the controller 192 (e.g., microcontroller) may be operable to receive information from the camera system 190. Further, the camera system 190 may be operable to receive information (e.g., image information) indicating the connectivity of the one or more conductive cables 106. For example and without limitation, the method may include providing visual verification, via the camera system 190 and/or the controller 192, that the one or more conductive cables are properly fastened between the housing 102/channels 110 and the one or more busbars 104.

In examples, the one or more inspection apertures 114 may be within the field of view for a lens of the camera system 190 to be confirmed via the controller 192. Further, the method may include focusing, via the camera system 190, on the one or more apertures 114 to determine whether a portion of the one or more conductive cables 106 is visible (e.g., by looking at the one or more inspection apertures 114). A portion of the one or more conductive cables 106 may be visually present through the one or more inspection apertures 114 to indicate a successful position (e.g., a structurally sufficient condition) of the one or more conductive cables 106 (e.g., sufficiently within the one or more channels 110. Further, the method may include transmitting an indication of successful assembly if the one or more conductive cables 106 are visible through the one or more inspection apertures 114. Upon the controller 192 receiving information that the one or more conductive cables 106 are not substantially visible through the one or more inspection apertures 114, the method may include determining, via the controller 192, improper/compromised positions (e.g., structurally insufficient condition) of the one or more conductive cables 106; and/or transmitting an indication of unsuccessful assembly.

The disclosure includes, without limitation, the following embodiments:

A system, comprising: a housing; one or more busbars; and one or more conductive cables disposed between the housing and the one or more busbars; wherein the one or more busbars comprise one or more apertures disposed in substantial alignment with one or more channels of the housing; and the one or more conductive cables are visible through the one or more apertures for visual inspection at the one or more channels.

The system according to any of the preceding embodiments, wherein the one or more channels correspond to areas where at least one of the one or more conductive cables are capable of pinching while connecting at least one busbar of the one or more busbars to the housing.

The system according to any of the preceding embodiments, wherein connecting the one or more busbars to the housing limits movement of the one or more conductive cables.

The system according to any of the preceding embodiments, wherein the one or more busbars are connected to the housing proximate a perimeter of the one or more busbars.

The system according to any of the preceding embodiments, the one or more busbars further comprising one or more fastening apertures for connecting the one or more busbars with the housing.

The system according to any of the preceding embodiments, wherein the one or more fastening apertures are disposed about a perimeter of the one or more busbars.

The system according to any of the preceding embodiments, wherein each of the one or more busbars comprise a greater quantity of the one or more fastening apertures than the one or more apertures.

The system according to any of the preceding embodiments, wherein the one or more apertures of a busbar of the one or more busbars comprise a first aperture and a second aperture.

The system according to any of the preceding embodiments, wherein the first aperture corresponds with a first fault location for a first conductive cable of the one or more conductive cables and the second aperture corresponds with a second fault location for a second conductive cable of the one or more conductive cables.

The system according to any of the preceding embodiments, wherein the first aperture and the second aperture are substantially the same size.

The system according to any of the preceding embodiments, wherein at least one of the one or more apertures is substantially oval-shaped.

The system according to any of the preceding embodiments, wherein the one or more busbars are substantially planar and form a top surface of the housing.

The system according to any of the preceding embodiments, wherein the housing comprises one or more tracks to route the one or more conductive cables, and the fault locations correspond to areas where the one or more tracks are likely to compromise a conductivity of the one or more conductive cables.

The system according to any of the preceding embodiments, wherein the one or cables are disposed within a viewing window of the one or more apertures such that a position of the one or more cables is capable of verification.

A system, comprising: a housing; one or more busbars; one or more conductive cables disposed between the housing and the one or more busbars; and a camera disposed substantially proximate the housing;

The system according to any of the preceding embodiments, wherein the one or more busbars comprise one or more apertures aligned with one or more channels of the housing; and a conductivity of the one or more conductive cables is verifiable by visual inspection through the one or more apertures via the camera.

The system according to any of the preceding embodiments, wherein the one or more channels route the one or more conductive cables between the housing and the one or more busbars.

The system according to any of the preceding embodiments, wherein the one or more apertures are disposed in substantial alignment with one or more fault locations to indicate whether the one or more conductive cables are disposed between one or more supports of the one or more channels and the one or more busbars.

The system according to any of the preceding embodiments, wherein the one or more conductive cables are in contact with the one or more busbars.

The system according to any of the preceding embodiments, wherein the one or more conductive cables are in contact with the housing.

The system according to any of the preceding embodiments, wherein the one or more busbars are disposed about 10 mm from the one or more conductive cables such that the one or more conductive cables are visible through the one or more apertures.

Various examples/embodiments are described herein for various apparatuses, systems, and/or methods. Numerous specific details are set forth to provide a thorough understanding of the overall structure, function, manufacture, and use of the examples/embodiments as described in the specification and illustrated in the accompanying drawings. It will be understood by those skilled in the art, however, that the examples/embodiments may be practiced without such specific details. In other instances, well-known operations, components, and elements have not been described in detail so as not to obscure the examples/embodiments described in the specification. Those of ordinary skill in the art will understand that the examples/embodiments described and illustrated herein are non-limiting examples, and thus it can be appreciated that the specific structural and functional details disclosed herein may be representative and do not necessarily limit the scope of the embodiments.

Reference throughout the specification to “examples, “in examples,” “with examples,” “various embodiments,” “with embodiments,” “in embodiments,” or “an embodiment,” or the like, means that a particular feature, structure, or characteristic described in connection with the example/embodiment is included in at least one embodiment. Thus, appearances of the phrases “examples, “in examples,” “with examples,” “in various embodiments,” “with embodiments,” “in embodiments,” or “an embodiment,” or the like, in places throughout the specification are not necessarily all referring to the same embodiment. Furthermore, the particular features, structures, or characteristics may be combined in any suitable manner in one or more examples/embodiments. Thus, the particular features, structures, or characteristics illustrated or described in connection with one embodiment/example may be combined, in whole or in part, with the features, structures, functions, and/or characteristics of one or more other embodiments/examples without limitation given that such combination is not illogical or non-functional. Moreover, many modifications may be made to adapt a particular situation or material to the teachings of the present disclosure without departing from the scope thereof.

It should be understood that references to a single element are not necessarily so limited and may include one or more of such element. Any directional references (e.g., plus, minus, upper, lower, upward, downward, left, right, leftward, rightward, top, bottom, above, below, vertical, horizontal, clockwise, and counterclockwise) are only used for identification purposes to aid the reader's understanding of the present disclosure, and do not create limitations, particularly as to the position, orientation, or use of examples/embodiments.

Joinder references (e.g., attached, coupled, connected, and the like) are to be construed broadly and may include intermediate members between a connection of elements, relative movement between elements, direct connections, indirect connections, fixed connections, movable connections, operative connections, indirect contact, and/or direct contact. As such, joinder references do not necessarily imply that two elements are directly connected/coupled and in fixed relation to each other. Connections of electrical components, if any, may include mechanical connections, electrical connections, wired connections, and/or wireless connections, among others. Uses of “e.g.” and “such as” in the specification are to be construed broadly and are used to provide non-limiting examples of embodiments of the disclosure, and the disclosure is not limited to such examples. Uses of “and” and “or” are to be construed broadly (e.g., to be treated as “and/or”). For example and without limitation, uses of “and” do not necessarily require all elements or features listed, and uses of “or” are inclusive unless such a construction would be illogical.

While processes, systems, and methods may be described herein in connection with one or more steps in a particular sequence, it should be understood that such methods may be practiced with the steps in a different order, with certain steps performed simultaneously, with additional steps, and/or with certain described steps omitted.

All matter contained in the above description or shown in the accompanying drawings shall be interpreted as illustrative only and not limiting. Changes in detail or structure may be made without departing from the present disclosure.

It should be understood that a controller, a system, and/or a processor as described herein may include a conventional processing apparatus known in the art, which may be capable of executing preprogrammed instructions stored in an associated memory, all performing in accordance with the functionality described herein. To the extent that the methods described herein are embodied in software, the resulting software can be stored in an associated memory and can also constitute means for performing such methods. Such a system or processor may further be of the type having ROM, RAM, RAM and ROM, and/or a combination of non-volatile and volatile memory so that any software may be stored and yet allow storage and processing of dynamically produced data and/or signals.

It should be further understood that an article of manufacture in accordance with this disclosure may include a non-transitory computer-readable storage medium having a computer program encoded thereon for implementing logic and other functionality described herein. The computer program may include code to perform one or more of the methods disclosed herein. Such embodiments may be configured to execute via one or more processors, such as multiple processors that are integrated into a single system or are distributed over and connected together through a communications network, and the communications network may be wired and/or wireless. Code for implementing one or more of the features described in connection with one or more embodiments may, when executed by a processor, cause a plurality of transistors to change from a first state to a second state. A specific pattern of change (e.g., which transistors change state and which transistors do not), may be dictated, at least partially, by the logic and/or code.

What is claimed is:

1. A system, comprising:
a housing;
one or more busbars; and
one or more conductive cables disposed between the housing and the one or more busbars;
wherein the one or more busbars comprise one or more apertures disposed in substantial alignment with one or more channels of the housing; and the one or more conductive cables are visible through the one or more apertures for visual inspection at the one or more channels.

2. The system of claim 1, wherein the one or more channels correspond to areas where at least one of the one or more conductive cables are capable of pinching while connecting at least one busbar of the one or more busbars to the housing.

3. The system of claim 2, wherein connecting the one or more busbars to the housing limits movement of the one or more conductive cables.

4. The system of claim 2, wherein the one or more busbars are connected to the housing proximate a perimeter of the one or more busbars.

5. The system of claim 1, the one or more busbars further comprising one or more fastening apertures for connecting the one or more busbars with the housing.

6. The system of claim 5, wherein the one or more fastening apertures are disposed about a perimeter of the one or more busbars.

7. The system of claim 6, wherein each of the one or more busbars comprise a greater quantity of the one or more fastening apertures than the one or more apertures.

8. The system of claim 1, wherein the one or more apertures of a busbar of the one or more busbars comprise a first aperture and a second aperture.

9. The system of claim 8, wherein the first aperture corresponds with a first fault location for a first conductive cable of the one or more conductive cables and the second aperture corresponds with a second fault location for a second conductive cable of the one or more conductive cables.

10. The system of claim 9, wherein the first aperture and the second aperture are substantially the same size.

11. The system of claim 1, wherein at least one of the one or more apertures is substantially oval-shaped.

12. The system of claim 1, wherein the one or more busbars are substantially planar and form a top surface of the housing.

13. The system of claim 9, wherein the housing comprises one or more tracks to route the one or more conductive cables, and the fault locations correspond to areas where the one or more tracks are likely to compromise a conductivity of the one or more conductive cables.

14. The system of claim 1, wherein the one or cables are disposed within a viewing window of the one or more apertures such that a position of the one or more cables is capable of verification.

15. A system, comprising:
a housing;
one or more busbars;
one or more conductive cables disposed between the housing and the one or more busbars; and
a camera disposed substantially proximate the housing;
wherein the one or more busbars comprise one or more apertures aligned with one or more channels of the housing; and a conductivity of the one or more conductive cables is verifiable by visual inspection through the one or more apertures via the camera.

16. The system of claim 15, wherein the one or more channels route the one or more conductive cables between the housing and the one or more busbars.

17. The system of claim 16, wherein the one or more apertures are disposed in substantial alignment with one or more fault locations to indicate whether the one or more conductive cables are disposed between one or more supports of the one or more channels and the one or more busbars.

18. The system of claim 15, wherein the one or more conductive cables are in contact with the one or more busbars.

19. The system of claim 18, wherein the one or more conductive cables are in contact with the housing.

20. The system of claim 15, wherein the one or more busbars are disposed about 10 mm from the one or more conductive cables such that the one or more conductive cables are visible through the one or more apertures.
